(19) United States
(12) Patent Application Publication
(10) Pub. No.: US 2010/0288350 A1
(43) Pub. Date: Nov. 18, 2010

(54) SOLAR CELL AND MANUFACTURING METHOD THEREOF

(76) Inventors: Shih-Wei Lee, Kaohsiung County (TW); Chi-Hung Hou, Taipei City (TW); Yen-Chun Chen, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 12/772,223

(22) Filed: May 2, 2010

(30) Foreign Application Priority Data
May 12, 2009 (TW) 098115617

(51) Int. Cl. H01L 31/00; H01L 31/18

(52) U.S. Cl. 136/256; 438/71; 257/E31.13

(57) ABSTRACT

The present invention discloses a solar cell and a manufacturing method. A top surface of a substrate is transformed into an active surface with a waved shape. Next, a conductive layer, a CIGS compound layer and a transparent conductive layer are sequentially formed on the active surface. The active surface with the waved shape is formed by a destructive forming method, so that the conductive layer, the CIGS compound layer and the transparent conductive layer formed on the active surface in the following step also have the waved shape. Accordingly, a light-absorbing area and a reacting area can be increased, and conversion efficiency of light energy being converted into the electric energy is raised.

### BACKGROUND OF THE INVENTION

1. Field of the Invention

The present invention relates to a solar cell, and more particularly, to a solar cell including a copper-indium-gallium-diselenide (CIGS) compound and a manufacturing method thereof.

2. Description of the Prior Art

In several well-known solar cells, the solar cell including a CIGS compound is a kind of solar cell having high conversion efficiency and low manufacturing cost, and a product of the CIGS solar cell also has good stability. Therefore, the CIGS solar cell has been one of the well-known solar cells with developing potential.

The aforementioned CIGS solar cell is formed by sequentially forming a molybdenum (Mo) layer, a CIGS compound layer and a transparent conductive layer on a substrate. The CIGS compound layer is used as a light-absorbing layer. When the light emits to the CIGS solar cell, energy of the light can be absorbed by the CIGS compound layer, and the energy of the light can be conversed into electric energy.

However, an energy conversion efficiency of the well-known CIGS solar cell is about 14%, and a difference between the energy conversion efficiency of the well-known CIGS solar cell and an ideal energy conversion efficiency still exists. Therefore, to raise the energy conversion efficiency of the CIGS solar cell and to increase utilization value in industry is an important objective in researching the CIGS solar cell.

### SUMMARY OF THE INVENTION

It is a primary objective of the present invention to provide a solar cell and a manufacturing method thereof to increase absorbed light and a reacting area, so that a conversion efficiency of light energy being converted into electric energy is raised.

According to the present invention, a solar cell is disclosed. The solar cell includes:
a substrate, a top surface of the substrate being a surface with a waved shape;
a conductive layer, disposed on the surface with the waved shape of the substrate, so that the conductive layer is a film with the waved shape;
a copper-indium-gallium-diselenide (CIGS) compound layer, disposed on a ripple surface of the conductive layer, so that the CIGS compound layer is a film with the waved shape; and
a transparent conductive layer, disposed on a top surface of the CIGS compound layer.

According to the present invention, a manufacturing method of a solar cell is disclosed. The manufacturing method of a solar cell includes:
providing a substrate, a top surface is defined on the substrate;
performing a surface-roughening method on the top surface of the substrate to form an uneven surface comprising a plurality of holes;
performing a shaping method on the uneven surface comprising the holes to form an active surface with a smoothly waved shape;
forming a conductive layer on the active surface of the substrate;
forming a CIGS compound layer on a top surface of the conductive layer; and
forming a transparent conductive layer on the CIGS compound layer.

The present invention transforms the top surface of the substrate into the surface with the waved shape, so that the conductive layer, the CIGS compound layer and the transparent conductive layer formed on the top surface of the substrate in the following steps also have surfaces with the waved shape due to the top surface of the substrate being the surface with the waved shape. Therefore, when the solar cell absorbs the sunlight, the surface with the waved shape can increase the number of the refracting light, and reduces the reflection of the sunlight, so that the absorption rate for the sunlight can be raised. In addition, the reacting area of the CIGS compound layer can be therefore increased, so that the conversion efficiency of the solar cell converting the light energy into electric energy is raised, and the current generated by the solar cell can be increased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a cross-sectional view of a solar cell according to a preferred embodiment of the present invention.

FIG. 2A through FIG. 2C are schematic diagrams illustrating steps of forming an active surface of a glass substrate with a waved shape according to the present invention.

FIG. 3A through FIG. 3D are schematic diagrams illustrating steps of forming a conductive layer, a CIGS compound layer and a transparent conductive layer on the active surface of the glass substrate according to the present invention.

### DETAILED DESCRIPTION

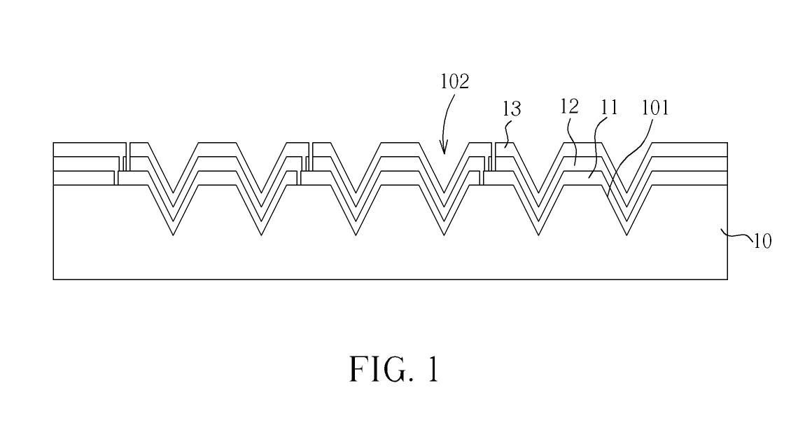

Please refer to FIG. 1, which is a schematic diagram illustrating a cross-sectional view of a solar cell according to a preferred embodiment of the present invention. As shown in FIG. 1, the solar cell includes a substrate 10, a conductive layer 11, a CIGS compound layer 12 and a transparent conductive layer 13.

The substrate can be a board selected from glass and plastic material. A top surface of the substrate has an active surface 101 with a waved shape, and the waved shape can be a plurality of peaks and a plurality of valleys arranged alternately in sequence. In this preferred embodiment, the top surface of the substrate 10 is transformed into the active surface 101 with the waved shape including a plurality of concavities 102. The concavities 102 can be V-shaped, inverted conoid, inverted pyramid-shaped holes.

The conductive layer 11 can be molybdenum (Mo), and is disposed on the active surface 101 of the substrate 10 with the concavities, so that the conductive layer is a film with a waved shape.

The CIGS compound layer 12 is copper-indium-gallium diselenide (CuIn₁₋ₓGaₓSe₂, CIGS), and the CIGS compound layer 12 is disposed on a top surface of the conductive layer 11, so that the CIGS compound layer is a film with a waved shape.

The transparent conductive layer 13 includes indium tin oxide (ITO) or Zinc oxide (ZnO), and the transparent conductive layer 13 is disposed on the CIGS compound layer 12.

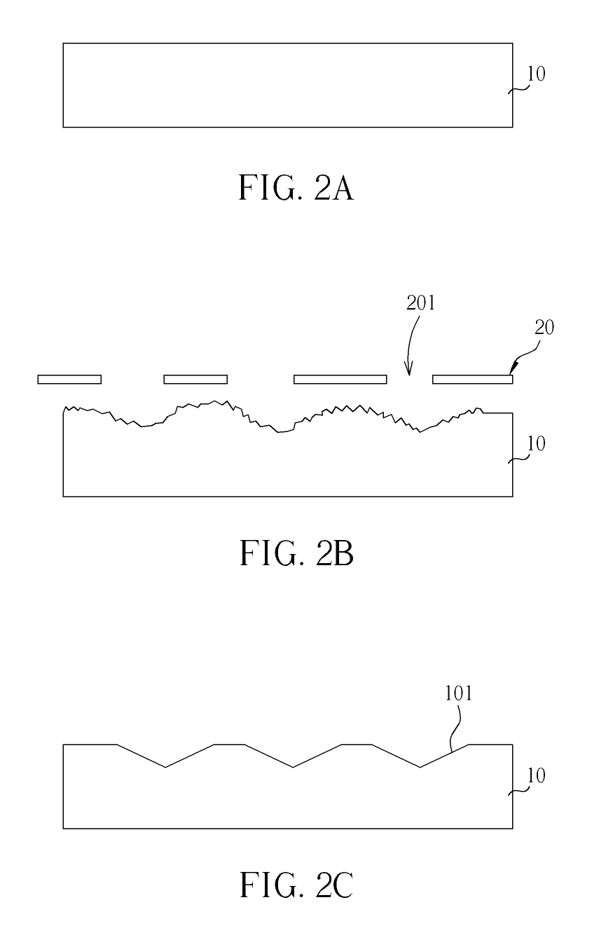

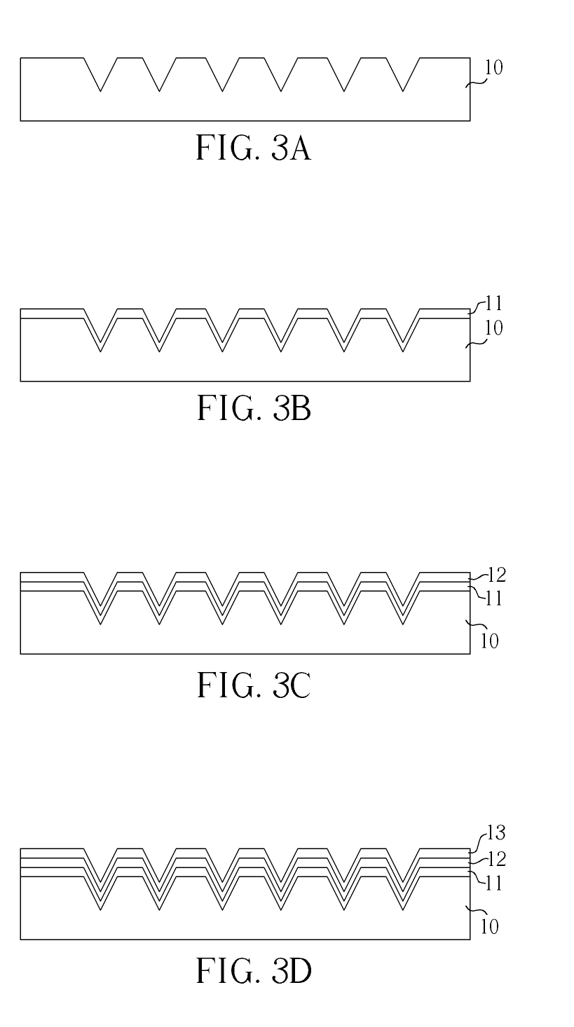

In order to describe a manufacturing method of the above-mentioned solar cell, referring to FIG. 2A through FIG. 2C and FIG. 3A through 3D, FIG. 2A through FIG. 2C are schematic diagrams illustrating steps of forming an active surface of a glass substrate with a waved shape according to the present invention, and FIG. 3A through FIG. 3C are schematic diagrams illustrating steps of forming a conductive layer, a CIGS compound layer and a transparent conductive layer on the active surface of the glass substrate according to the present invention. As shown in FIG. 2A through 2C and FIG. 3A through FIG. 3D, the manufacturing method of the solar cell of the present invention is detailed in the following description. First, a substrate 10 is provided, and a top surface is defined on the substrate 10. The substrate can be a glass substrate or a plastic substrate (as shown in FIG. 2A). This preferred embodiment takes the glass substrate as an example.

Next, a surface-roughening method is performed on the top surface of the substrate 10 to form an uneven surface including a plurality of holes, and the surface-roughening method utilizes a destructive forming method, such as a sandblasting method, a laser processing method, an etching method or other forming method being capable of forming the a plurality of holes on the top surface of the substrate 10. As shown in FIG. 2B, in this embodiment, the surface-roughening method is the sandblasting method, and the surface-roughening method in combination with a mask having a plurality of through holes arranged in a pattern is performed to form a plurality of holes at predetermined positions on the top surface of the substrate 10, so that the top surface of the substrate 10 is transformed into the uneven surface with a plurality of peaks and a plurality of valleys arranged alternately in sequence. In addition, the present invention also can utilize a laser processing method to form the holes having predetermined depth respectively at each predetermined position of the substrate 10 under control of a computer, so that the top surface of the substrate 10 has the uneven surface. When the thickness of the substrate 10 is 3 millimeter (mm), the depth of the holes on the substrate 10 is preferable to be substantially between 1.4 mm and 1.6 mm, and the width of the holes is preferable to be substantially between 1.6 mm and 1.8 mm.

A shaping method is performed on the uneven surface of the substrate 10 including the holes to form an active surface 101 with a smoothly waved shape, and the waved shape has the peaks and the valleys arranged alternately in sequence. As shown in FIG. 2A through 2C, in this preferred embodiment, the substrate is a glass substrate 10, and a sandblasting method is performed to form the uneven surface on the glass substrate 10. Then, hydrofluoric acid (HF) is further utilized to remove sharp parts of the uneven surface of the glass substrate formed in the sandblasting method, so that the uneven surface is transformed into the active surface 101 with the waved shape.

As shown in FIG. 3A through 3B, a conductive layer is formed on the active surface 101 of the substrate 10. The material of the conductive layer 11 can be molybdenum, and the conductive layer 11 is formed on the active surface of the substrate 10 by a sputtering method.

As shown in FIG. 3C, a CIGS compound layer 12 is formed on a top surface of the conductive layer 11 to be a light-absorbing layer, and a step of forming the CIGS compound layer 12 on the conductive layer 11 can be performed by utilize CIGS in combination with a method of selected from an evaporation method and a screen printing method, etc.

As shown in FIG. 3D, a transparent conductive layer 13 is formed on the CIGS compound layer 12, and the transparent conductive layer 13 can be a material selected from indium tin oxide and zinc oxide, etc. The transparent conductive layer 13 can be formed by a deposition method, such as a sputtering method.

The manufacturing method of the solar cell in the present invention further includes a cutting process after forming the transparent conductive layer 13, and the cutting process is performed to generate a cut gap. The cut gap has a pattern and extends from the top surface of the transparent conductive layer 13 to the substrate 10, so that a plurality of solar cell units is formed on a single substrate.

As the above-mentioned description, the present invention transforms the top surface of the substrate into the surface with the waved shape, so that the conductive layer, the CIGS compound layer and the transparent conductive layer formed on the top surface of the substrate in the following steps also have the surface with the waved shape due to the top surface of the substrate being the surface with the waved shape. Therefore, when the solar cell absorbs the sunlight, the surface with the waved shape can increase the number of the refracting light, and reduces the reflection of the sunlight, so that the absorption rate for the sunlight can be raised. By the design of the ripple surface, the reacting area of the CIGS compound layer is increased, so that the conversion efficiency of the solar cell converting the light energy into electric energy is raised, and the current generated by the solar cell can be increased. Therefore, by the design of the present invention, the utilization value of the solar cell in industry can be promoted.

Those skilled in the art will readily observe that numerous modifications and alterations of the device and method may be made while retaining the teachings of the invention.

What is claimed is:

1. A solar cell, comprising:
a substrate, a top surface of the substrate being a surface with a waved shape;
a conductive layer, disposed on the surface with the waved shape of the substrate, so that the conductive layer is a film with the waved shape;
a copper-indium-gallium-diselenide (CIGS) compound layer, disposed on a ripple surface of the conductive layer, so that the CIGS compound layer is a film with the waved shape; and
a transparent conductive layer, disposed on a top surface of the CIGS compound layer.

2. The solar cell of claim 1, wherein the surface with the waved shape of the substrate comprises a plurality of concavities.

3. The solar cell of claim 2, wherein the concavities are V-shaped grooves.

4. The solar cell of claim 2, wherein the concavities are inverted conoid.

5. The solar cell of claim 2, wherein the concavities are inverted pyramid-shaped.

6. The solar cell of claim 1, wherein the substrate is a glass substrate, the conductive layer is a molybdenum (Mo) film, and the transparent conductive layer is an indium tin oxide (ITO) film.

7. A manufacturing method of a solar cell, comprising:
providing a substrate, a top surface is defined on the substrate;
performing a surface-roughening method on the top surface of the substrate to form an uneven surface comprising a plurality of holes;
performing a shaping method on the uneven surface comprising the holes to form an active surface with a smoothly waved shape;
forming a conductive layer on the active surface of the substrate;
forming a CIGS compound layer on a top surface of the conductive layer; and
forming a transparent conductive layer on the CIGS compound layer.

8. The manufacturing method of the solar cell of claim 7, wherein the surface-roughening method is a destructive forming method.

9. The manufacturing method of the solar cell of claim 8, wherein the destructive forming method is a forming method of a sandblasting method in combination with a mask having a set of through holes arranged in a pattern.

10. The manufacturing method of the solar cell of claim 8, wherein the destructive forming method is a laser processing method.

11. The manufacturing method of the solar cell of claim 7, wherein the substrate is a glass substrate, and the shaping method is to remove sharp parts of the uneven surface of the glass substrate by utilizing hydrofluoric acid, so that the active surface with the smoothly waved shape is formed.

12. The manufacturing method of the solar cell of claim 11, wherein the conductive layer is formed on the active surface by a sputtering method in combination with molybdenum.

13. The manufacturing method of the solar cell of claim 12, wherein the CIGS compound layer is formed on a top surface of the conductive layer by an evaporation method.

14. The manufacturing method of the solar cell of claim 11, wherein the CIGS compound layer is formed on a top surface of the conductive layer by an evaporation method.

15. The manufacturing method of the solar cell of claim 14, wherein the transparent conductive layer is formed on the CIGS compound layer by performing a sputtering method in combination with indium tin oxide.

16. The manufacturing method of the solar cell of claim 11, wherein the transparent conductive layer is formed on the CIGS compound layer by performing a sputtering method in combination with indium tin oxide.
